(19) United States
(12) Patent Application Publication
(10) Pub. No.: US 2025/0240032 A1
(43) Pub. Date: Jul. 24, 2025

(54) METHOD FOR ADJUSTING COMPRESSION RATE AND ELECTRONIC DEVICE

(71) Applicant: MEDIATEK INC., Hsinchu City (TW)

(72) Inventors: Chia-Wei TAI, Hsinchu City (TW); Chun-Ming KUO, Hsinchu City (TW)

(21) Appl. No.: 18/985,934

(22) Filed: Dec. 18, 2024

Related U.S. Application Data
(60) Provisional application No. 63/614,944, filed on Dec. 27, 2023.

(51) Int. Cl. H03M 7/30

(52) U.S. Cl. CPC H03M 7/6011; H03M 7/6058

(57) ABSTRACT

A method for adjusting compression rate is provided. The method includes compressing data at a compression rate and storing the data into a memory using a processing circuit. The method further includes calculating a compression rate adjustment parameter based on each time duration for reading or writing the memory in a first specific period of time and a time threshold using the processing circuit. The method further includes adjusting the compression rate based on the compression rate adjustment parameter using a processing circuit.

### CROSS REFERENCE TO RELATED APPLICATIONS

This application claims priority of U.S. Provisional Application Ser. No. 63/614,944, filed on 2023 Dec. 27, the entirety of which is incorporated by reference herein.

### BACKGROUND OF THE INVENTION

### Field of the Invention

The present invention relates to the data compression, and, in particular, to determining the compression rate of the data compression.

### Description of the Related Art

User equipment (UE) stores data of a current transmission in memory in order to implement a retransmission process. To complete tasks within the required time, high memory throughput is required, and thus the data is stored in the memory after being compressed. If the compression rate is too high, the compressed data is unable to be recovered perfectly. If the compression rate is too low, the memory throughput will be decreased, and the time requirements on the tasks cannot be met. Thus, a method for determining a proper compression rate is required.

### BRIEF SUMMARY OF THE INVENTION

An embodiment of the present invention provides a method for adjusting compression rate. The method comprises compressing the data at a compression rate and storing the data into a memory using a processing circuit. The method further comprises calculating a compression rate adjustment parameter based on each time duration for reading or writing the memory in a first specific period of time and a time threshold using the processing circuit. The method further comprises adjusting the compression rate based on the compression rate adjustment parameter using a processing circuit.

An embodiment of the present invention provides an electronic device comprising a memory and a processing circuit. The processing circuit is configured to compress the data at a compression rate and store the data into the memory; calculate a compression rate adjustment parameter, based on each time duration for reading or writing the memory in a first specific period of time and a time threshold; and adjust the compression rate based on the compression rate adjustment parameter.

### BRIEF DESCRIPTION OF THE DRAWINGS

The present invention can be more fully understood by reading the subsequent detailed description and examples with references made to the accompanying drawings, wherein:

FIG. 1 is a block diagram of the electronic device in accordance to embodiments of the present disclosure;

FIG. 2 is a flow diagram of the method for determining the compression rate in accordance to embodiments of the present disclosure;

FIG. 3 is a schematic diagram which illustrates the method for calculating the compression rate adjustment parameter and adjusting the compression rate in accordance to the embodiments of the present disclosure; and

FIG. 4 is a schematic diagram which illustrates the method for calculating the compression rate adjustment parameter and adjusting the compression rate in accordance to the embodiments of the present disclosure.

### DETAILED DESCRIPTION OF THE INVENTION

The following description is made for the purpose of illustrating the general principles of the invention and should not be taken in a limiting sense. The scope of the invention is best determined by reference to the appended claims.

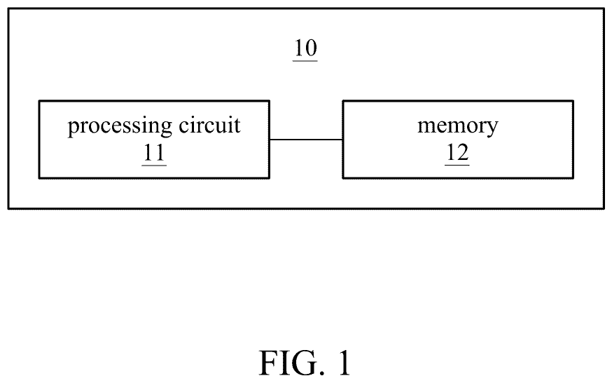

FIG. 1 is a block diagram of the electronic device 10 in accordance to embodiments of the present disclosure. In some embodiments, the electronic device 10 may be a mobile apparatus, a wearable apparatus, an Internet of thing (IoT) apparatus, or a computing apparatus. For example, the electronic device 10 is a smartphone, a tablet computer, a notebook computer, a desktop computer, a head-mounted display (HMD), or a smartwatch. Electronic device 10 comprises processing circuit 11 and memory 12. Furthermore, the electronic device 10 may include other components, which are not shown in FIG. 1. In some embodiments, the electronic device 10 further includes a display, a touch screen, an user interface device (e.g. mouse and keyboard), an antenna, or an internal power supply. These components may be connected via a bus.

The processing circuit 11 controls operations of the electronic device 10. The processing circuit 11 provides the required process ability to perform operating systems, programs, software, modules, applications, and functions of the electronic device 10. In some embodiments, processing circuit 11 may be implemented in the form of hardware with electronic components, such as transistors, diodes, capacitors, resistors, or inductors. These components are configured and arranged to achieve specific purposes in accordance with the present disclosure. The processing circuit 11 may include a general purpose micro-processor, a central processing unit (CPU), an application processor, a graphics processing unit (GPU), an image signal processor, a controller, a digital signal processor, and/or related chip set. The processing circuit 11 may be implemented in the form of one or more integrated-circuit (IC) chips such as one or more processors.

The memory 12 stores data required by the processing circuit 11. The memory 12 may include non-volatile memories, such as read only memory (ROM) and flash memory. The memory 12 may also include volatile memories, such as dynamic random access memory (DRAM) and static random access memory (SRAM). In some embodiments, the processing circuit 11 is configured to implement a plurality of applications, such as voice application, video application, and gaming applications. The memory 12 is shared by implemented via the processing circuit 11. In some embodiments, at least a prat of these applications may simultaneously write the data into the memory 12 and read the data from the memory 12. In some embodiments, the memory 12 stores at least one program (e.g. computer-readable instruction). The program can be read by the processor 11. When the program is operated by the processor 11, the program causes the processor 11 to implement methods according to the embodiments of the present disclosure.

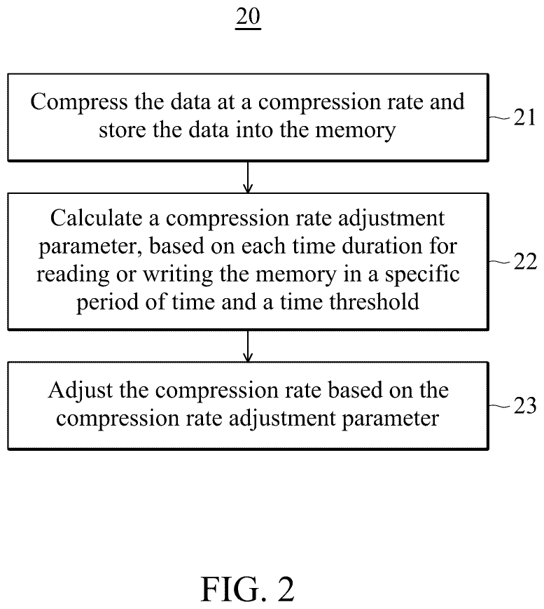

FIG. 2 is a flow diagram of the method 20 for adjusting the compression rate in accordance to embodiments of the present disclosure. Method 20 may be implemented in the electronic device 10. In operation 21, the processing circuit 11 compresses the data at a compression rate and stores/writes the data into the memory 12. The compression rate is defined as:

$$\frac{uncompressed data size}{compressed data size}$$

The uncompressed data size is the data size before the data has been compressed (e.g. bits), and the compressed data size is the data size after the data has been compressed (e.g. bits). The data may be generated by the applications. The processing circuit 11 is also configured to read the data from the memory 12 and decompress the data.

In operation 22, processing circuit 11 calculates a compression rate adjustment parameter, based on each time duration for reading or writing the memory 12 in a specific period of time and a time threshold. In a specific period of time, the memory 12 may be read or written several times. Whenever the memory 12 is read or written, it takes a time duration for the processing circuit 11 (or the applications) to read the data from the memory 12 or write the data to the memory 12. In some embodiments, the time threshold is a hard-real time (HRT) limit which indicates the reading or writing operation has to be finished within a period of time (e.g. in ms). The processing circuit 11 is configured to record each of the time durations for reading or writing the memory 12 in the specific period of time, and calculate the compression rate adjustment parameter according to the recorded time duration and a time threshold.

In operation 23, the processing circuit 11 adjusts the compression rate based on the compression rate adjustment parameter. The methods for calculating the compression rate adjustment parameter and adjusting the compression rate are described below in more detail.

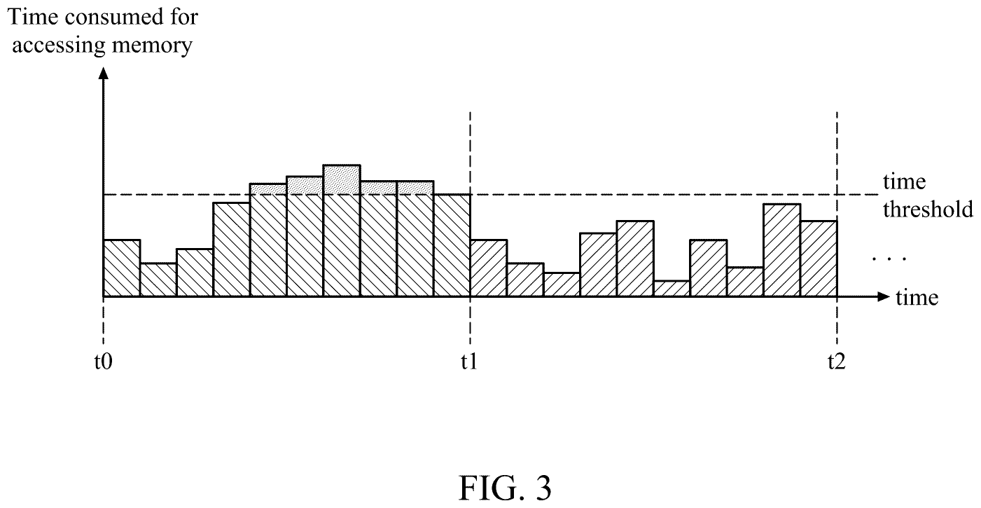

FIG. 3 is a schematic diagram which illustrates the method for calculating the compression rate adjustment parameter and adjusting the compression rate in accordance to the embodiments of the present disclosure. The horizontal axis of FIG. 3 is time. The vertical axis of FIG. 3 is the time duration for accessing (reading or writing) the memory 12. Each bar in the FIG. 3 illustrates the time duration for reading/writing one piece of data (e.g. an information packet) from/to the memory 12. From time point to t0 time point t1, the processing circuit 11 is configured to record each of the time durations for reading or writing the memory 12. Time point t0 to time point t1 may be referred to as a monitoring phase. Then, on time point t1, the processing circuit 11 is configured to calculate the compression rate adjustment parameter. Time point t1 may be referred to as a decision phase. In this embodiment, the compression rate adjustment parameter is a failure rate, which is defined as:

C/N

C is the total number of times that the time duration for reading or writing the memory 12 is higher than the time threshold in the specific period of time (e.g. from time point t0 to time point t1), and N is the total number of times that the memory 12 is read or written in the specific period of time (e.g. from time point t0 to time point t1). The compression rate adjustment parameter is equal to the total number of times that the time duration for reading or writing the memory 12 is higher than the time threshold in the specific period of time divided by the total number of times that the memory 12 is read or written in the specific period of time. In this embodiment, N is 10. The 5^{th}˜9^{th} data access spend the time duration higher than the time threshold, so C is 5. Thus, the compression rate adjustment parameter is 0.5 in this embodiment.

After the compression rate adjustment parameter is calculated, the processing circuit 11 is configured to adjust the compression rate based on the compression rate adjustment parameter. In this embodiment, the processing circuit 11 is configured to increase the compression rate when the compression rate adjustment parameter is higher than the first threshold. The processing circuit 11 is configured to keep the compression rate unchanged when the compression rate adjustment parameter is higher than the second threshold and lower than the first threshold. The processing circuit 11 is configured to decrease the compression rate when the compression rate adjustment parameter is lower than the second threshold. For a non-limiting example, the first threshold is 20%, and the second threshold is 5%. The compression rate is increased by 0.7 and decreased by 0.3. Then, the processing circuit 11 is configured to compress the data at the compression rate which has been adjusted and store the data into the memory 12 in the period of time preceding the period of time between time point t0 and time point t1 (e.g. time point t1 to time point t2).

In this embodiment, when the compression rate adjustment parameter is high, it means that there are many data access fail the time threshold. Thus, it is beneficial to increase the compression rate so as to compress the data to a smaller size and increase the throughput of the memory 12. On the other hand, when the compression rate adjustment parameter is low, it means that few data access fail the time threshold. Thus, it is beneficial to decrease the compression rate so as to prevent the data from unrecoverable compression and increase the quality of the decompressed data.

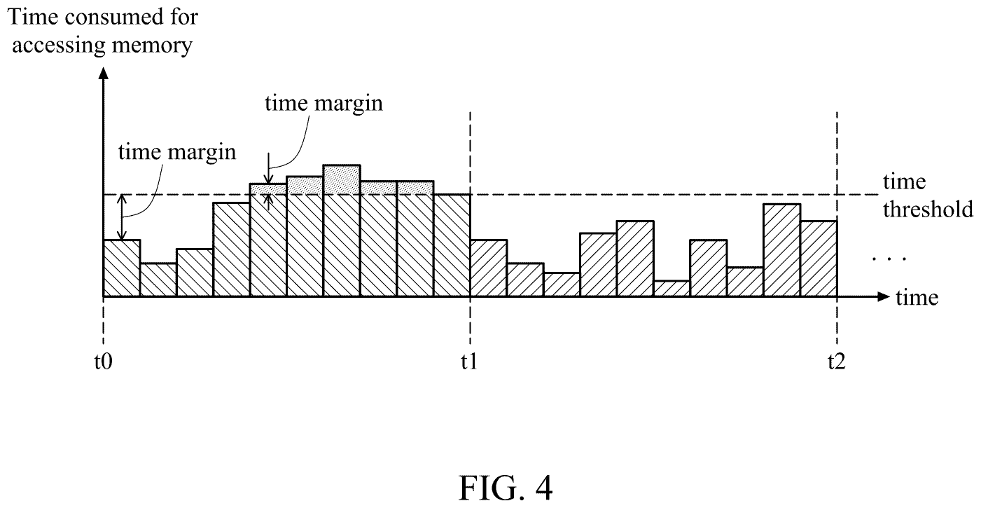

FIG. 4 is a schematic diagram which illustrates the method for calculating the compression rate adjustment parameter and adjusting the compression rate in accordance to the embodiments of the present disclosure. FIG. 4 is similar to FIG. 3. In this embodiment, the compression rate adjustment parameter is a HRT margin, which is defined as:

$${\sum }_{i = 1}^{N} ( time threshold - {T}_{i} )$$

N is the total number of times that the memory 12 is read or written in the specific period of time (e.g. time point t0 to time point t1), and Tᵢ is the i^{th} time duration for reading or writing the memory 12 (i.e. the time duration for the i^{th} memory access). The (time threshold−Tᵢ) may be referred to as the time margin (i.e. the time margin is equal to the time threshold minus the time duration for reading or writing the memory). The processing circuit 11 is configured to calculate the time margin for each time that the memory 12 is read or written in the specific period of time to calculate the compression rate adjustment parameter. In this embodiment, the compression rate adjustment parameter is equal to the sum of all of the time margins of each time that the memory is read or written in the specific period of time.

After the compression rate adjustment parameter is calculated, the processing circuit 11 is configured to adjust the compression rate based on the compression rate adjustment parameter. In this embodiment, the processing circuit 11 is configured to increase the compression rate when the compression rate adjustment parameter is lower than the first threshold. The processing circuit 11 is configured to keep the compression rate unchanged when the compression rate adjustment parameter is higher than the first threshold and lower than the second threshold. The processing circuit 11 is configured to decrease the compression rate when the compression rate adjustment parameter is higher than the second threshold. Alternatively, in this embodiment, the processing circuit 11 is configured to decrease the compression rate when the compression rate adjustment parameter is positive. The processing circuit 11 is configured to keep the compression rate unchanged when the compression rate adjustment parameter is equal to zero. The processing circuit 11 is configured to increase the compression rate when the compression rate adjustment parameter is negative. For a non-limiting example, the compression rate is increased by 0.7 and decreased by 0.3. Then, the processing circuit 11 is configured to compress the data at the compression rate which has been adjusted and store the data into the memory 12 in a period of time preceding the period of time between time point t0 and time point t1 (e.g. time point t1 to time point t2).

If the time duration for reading or writing the memory 12 is higher than the time threshold, the time margin will be negative. Thus, it is beneficial to increase the compression rate when the compression rate adjustment parameter is negative or lower than the threshold. On the other hand, if the time duration for reading or writing the memory 12 is lower than the time threshold, the time margin will be positive. Thus, it is beneficial to decrease the compression rate when the compression rate adjustment parameter is positive or higher than the threshold.

Refer to FIG. 4, in another embodiment, the compression rate adjustment parameter is a normalized HRT margin, which is defined as:

$$\frac{1}{N \cdot time threshold} {\sum }_{i = 1}^{N} ( time trethoshold - {T}_{i} )$$

N is the total number of times that the memory 12 is read or written in the specific period of time (e.g. time point t0 to time point t1), and Tᵢ is the i^{th} time duration for reading or writing the memory 12 (i.e. the time duration for the i^{th} memory access). The (time threshold−Tᵢ) may be referred to as the time margin (i.e. the time margin is equal to the time threshold minus the time duration for reading or writing the memory). The (Σᵢ₌₁^{N} (time trethoshold−Tᵢ)) may be referred to as the total time margin (i.e. the total time margin is equal to the sum of all of the time margins of each time that the memory is read or written in the specific period of time). The (N·time threshold) may be referred to as the normalize parameter (i.e. the normalization parameter is equal to the total number of times that the memory is read or written in the specific period of time multiplied by the time threshold). The processing circuit 11 is configured to calculate the time margin of each time that the memory 12 is read or written in the specific period of time, calculate the total time margin, and calculate the normalization parameter to calculate the compression rate adjustment parameter. In this embodiment, the compression rate adjustment parameter is equal to the total time margin divided by the normalization parameter.

After the compression rate adjustment parameter is calculated, the processing circuit 11 is configured to adjust the compression rate based on the compression rate adjustment parameter. In this embodiment, the processing circuit 11 is configured to increase the compression rate when the compression rate adjustment parameter is lower than the first threshold. The processing circuit 11 is configured to keep the compression rate unchanged when the compression rate adjustment parameter is higher than the first threshold and lower than the second threshold. The processing circuit 11 is configured to decrease the compression rate when the compression rate adjustment parameter is higher than the second threshold. In some embodiments, the first threshold and the second threshold are not 0. For a non-limiting example, the first threshold is −10%, and the second threshold is 30%. The compression rate is increased by 0.7 and decreased by 0.3. Then, the processing circuit 11 is configured to compress the data at the compression rate which has been adjusted and store the data into the memory 12 in the period of time preceding the period of time between time point t0 and time point t1 (e.g. time point t1 to time point t2).

After being normalized, the compression rate adjustment parameter is able to more accurately reflect the average of the time duration for accessing the memory 12. When most of the data access fail the time threshold or takes the time duration close to the time threshold, the time margin will be small or negative, and the compression rate adjustment parameter will be low. Thus, it is beneficial to increase the compression rate when the compression rate adjustment parameter is low. On the other hand, when most of the data access fulfill the time threshold or takes the time duration much lower than the time threshold, the time margin will be large and positive, and the compression rate adjustment parameter will be high. Thus, it is beneficial to increase the compression rate when the compression rate adjustment parameter is high.

An electronic device and a method for adjusting compression rate are provided. The electronic device and the method can adjust the compression rate based on the time duration for accessing the memory in the past period of time and the time threshold in order to apply a proper compression rate. The electronic device and the method can minimize the chance of losing data while maximize the memory throughput as much as possible.

While the invention has been described by way of example and in terms of the preferred embodiments, it should be understood that the invention is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A method for adjusting compression rate, comprising:
compressing, via a processing circuit, the data at a compression rate and storing the data into a memory;
calculating, via the processing circuit, a compression rate adjustment parameter, based on each time duration for reading or writing the memory in a first specific period of time and a time threshold; and
adjusting, via the processing circuit, the compression rate based on the compression rate adjustment parameter.

2. The method as claimed in claim 1, wherein the compression rate adjustment parameter is equal to a total number of times that the time duration for reading or writing the memory is higher than the time threshold in the first specific period of time divided by a total number of times that the memory is read or written in the first specific period of time.

3. The method as claimed in claim 2, wherein the operation of adjusting the compression rate based on the compression rate adjustment parameter comprises:
increasing the compression rate when the compression rate adjustment parameter is higher than a first threshold;
keeping the compression rate unchanged when the compression rate adjustment parameter is higher than a second threshold and lower than the first threshold; and
decreasing the compression rate when the compression rate adjustment parameter is lower than the second threshold.

4. The method as claimed in claim 1, wherein the operation of calculating the compression rate adjustment parameter comprises:
calculating a time margin for each time that the memory is read or written in the first specific period of time, wherein the time margin is equal to the time threshold minus the time duration for reading or writing the memory;
wherein the compression rate adjustment parameter is equal to the sum of all of the time margins of each time that the memory is read or written in the first specific period of time.

5. The method as claimed in claim 4, wherein the operation of adjusting the compression rate based on the compression rate adjustment parameter comprises:
increasing the compression rate when the compression rate adjustment parameter is lower than a first threshold;
keeping the compression rate unchanged when the compression rate adjustment parameter is higher than the first threshold and lower than a second threshold; and
decreasing the compression rate when the compression rate adjustment parameter is higher than the second threshold.

6. The method as claimed in claim 4, wherein the operation of adjusting the compression rate based on the compression rate adjustment parameter comprises:
increasing the compression rate when the compression rate adjustment parameter is negative;
keeping the compression rate unchanged when the compression rate adjustment parameter is equal to zero; and
decreasing the compression rate when the compression rate adjustment parameter is positive.

7. The method as claimed in claim 1, wherein the operation of calculating the compression rate adjustment parameter comprises:
calculating a time margin for each time that the memory is read or written in the first specific period of time, wherein the time margin is equal to the time threshold minus the time duration for reading or writing the memory;
calculating a total time margin, wherein the total time margin is equal to the sum of all of the time margins of each time that the memory is read or written in the first specific period of time; and
calculating a normalization parameter, wherein the normalization parameter is equal to a total number of times that the memory is read or written in the first specific period of time multiplied by the time threshold;
wherein the compression rate adjustment parameter is equal to the total time margin divided by the normalization parameter.

8. The method as claimed in claim 7, wherein the operation of adjusting the compression rate based on the compression rate adjustment parameter comprises:
increasing the compression rate when the compression rate adjustment parameter is lower than a first threshold;
keeping the compression rate unchanged when the compression rate adjustment parameter is higher than the first threshold and lower than a second threshold; and
decreasing the compression rate when the compression rate adjustment parameter is higher than the second threshold.

9. The method as claimed in claim 1, wherein the memory is shared by a plurality of applications implemented via the processing circuit.

10. The method as claimed in claim 1, further comprising:
compressing, via the processing circuit, the data at the compression rate which has been adjusted and storing the data into the memory, in a second specific period of time preceding the first specific period of time.

11. An electronic device, comprising:
a memory; and
a processing circuit, configured to:
compress the data at a compression rate and store the data into the memory;
calculate a compression rate adjustment parameter, based on each time duration for reading or writing the memory in a first specific period of time and a time threshold; and
adjust the compression rate based on the compression rate adjustment parameter.

12. The electronic device as claimed in claim 11, wherein the compression rate adjustment parameter is equal to a total number of times that the time duration for reading or writing the memory is higher than the time threshold in the first specific period of time divided by a total number of times that the memory is read or written in the first specific period of time.

13. The electronic device as claimed in claim 12, wherein the processing circuit is further configured to:
increase the compression rate when the compression rate adjustment parameter is higher than a first threshold;
keep the compression rate unchanged when the compression rate adjustment parameter is higher than a second threshold and lower than the first threshold; and
decrease the compression rate when the compression rate adjustment parameter is lower than the second threshold.

14. The electronic device as claimed in claim 11, wherein the processing circuit is further configured to:
calculate a time margin for each time that the memory is read or written in the first specific period of time, wherein the time margin is equal to the time threshold minus the time duration for reading or writing the memory;
wherein the compression rate adjustment parameter is equal to the sum of each of the time margins of each time that the memory is read or written in the first specific period of time.

15. The electronic device as claimed in claim 14, wherein the processing circuit is further configured to:
increase the compression rate when the compression rate adjustment parameter is lower than a first threshold;
keep the compression rate unchanged when the compression rate adjustment parameter is higher than the first threshold and lower than a second threshold; and
decrease the compression rate when the compression rate adjustment parameter is higher than the second threshold.

16. The electronic device as claimed in claim 14, wherein the processing circuit is further configured to:
increase the compression rate when the compression rate adjustment parameter is negative;
keep the compression rate unchanged when the compression rate adjustment parameter is equal to zero; and
decrease the compression rate when the compression rate adjustment parameter is positive.

17. The electronic device as claimed in claim 11, wherein the processing circuit is further configured to:
calculate a time margin for each time that the memory is read or written in the first specific period of time, wherein the time margin is equal to the time threshold minus the time duration for reading or writing the memory;
calculate a total time margin, wherein the total time margin is equal to the sum of each of the time margins of each time that the memory is read or written in the first specific period of time; and
calculate a normalization parameter, wherein the normalization parameter is equal to a total number of times that the memory is read or written in the first specific period of time multiplied by the time threshold;
wherein the compression rate adjustment parameter is equal to the total time margin divided by the normalization parameter.

18. The electronic device as claimed in claim 17, wherein the processing circuit is further configured to:
increase the compression rate when the compression rate adjustment parameter is lower than a first threshold;
keep the compression rate unchanged when the compression rate adjustment parameter is higher than the first threshold and lower than a second threshold; and
decrease the compression rate when the compression rate adjustment parameter is higher than the second threshold.

19. The electronic device as claimed in claim 11, wherein the memory is shared by a plurality of applications implemented via the processing circuit.

20. The electronic device as claimed in claim 11, wherein the processing circuit is further configured to compress the data at the compression rate which has been adjusted and storing the data into the memory, in a second specific period of time preceding the first specific period of time.
